(19) United States
(12) Patent Application Publication
(10) Pub. No.: US 2026/0165188 A1
(43) Pub. Date: Jun. 11, 2026

(54) SEMICONDUCTOR MODULE AND METHOD OF MANUFACTURING SEMICONDUCTOR MODULE

(71) Applicant: FUJI ELECTRIC CO., LTD., Kawasaki-shi (JP)

(72) Inventor: Kazuma KAWAMURA, Matsumoto-city (JP)

(73) Assignee: FUJI ELECTRIC CO., LTD., Kawasaki-shi (JP)

(21) Appl. No.: 19/064,991

(22) Filed: Feb. 27, 2025

(30) Foreign Application Priority Data
Apr. 3, 2024 (JP) 2024-060419

(51) Int. Cl. H10W 74/10; H10W 70/60; H10W 74/01; H10W 74/47

(52) U.S. Cl. CPC H10W 74/121; H10W 70/60; H10W 74/01; H10W 74/47

(57) ABSTRACT

A semiconductor module, including: a stacked substrate; a semiconductor device mounted on the stacked substrate via a bonding layer; an encapsulating resin encapsulating the semiconductor device, the bonding layer, and the stacked substrate; and a low-elastic-modulus element provided at a surface of the encapsulating resin above the semiconductor device, the low-elastic-modulus element having an elastic modulus that is lower than an elastic modulus of the encapsulating resin. The low-elastic-modulus element has a storage modulus that is a relative elastic modulus of 0.83% or more but less than 100%, when a storage modulus of the encapsulating resin is 100%.

### CROSS REFERENCE TO RELATED APPLICATIONS

This application is based upon and claims the benefit of priority of the prior Japanese Patent Application No. 2024-060419, filed on Apr. 3, 2024, the entire contents of which are incorporated herein by reference.

### BACKGROUND OF THE INVENTION

### 1. Field of the Invention

Embodiments of the disclosure relate to a semiconductor module and a method of manufacturing a semiconductor module.

### 2. Description of the Related Art

A conventionally proposed semiconductor device that is capable of suppressing peeling between an encapsulant and a case containing an inorganic filler and polyphenylene sulfide does so by exposing the inorganic filler from a matrix at a surface that faces the encapsulant of the case (for example, refer to Japanese Laid-Open Patent Publication No. 2024-000325).

### SUMMARY OF THE INVENTION

According to an embodiment of the present disclosure, a semiconductor module includes: a stacked substrate; a semiconductor device mounted on the stacked substrate via a bonding layer; an encapsulating resin encapsulating the semiconductor device, the bonding layer, and the stacked substrate; and a low-elastic-modulus element provided at a surface of the encapsulating resin above the semiconductor device, the low-elastic-modulus element having an elastic modulus that is lower than an elastic modulus of the encapsulating resin. The low-elastic-modulus element has a storage modulus that is a relative elastic modulus of 0.83% or more but less than 100%, when a storage modulus of the encapsulating resin is 100%.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting configuration of a power semiconductor module according to an embodiment.

FIG. 2 is a top view depicting a structure of the power semiconductor module according to the embodiment.

FIG. 3 is a cross-sectional view schematically depicting a state of the power semiconductor module according to the embodiment during manufacture according to the first method of manufacturing.

FIG. 4 is a cross-sectional view schematically depicting a state of the power semiconductor module according to the embodiment during manufacture according to the first method of manufacturing.

FIG. 5 is a cross-sectional view schematically depicting a state of the power semiconductor module according to the embodiment during manufacture according to the first method of manufacturing.

FIG. 6 is a cross-sectional view schematically depicting a state of the power semiconductor module according to the embodiment during manufacture according to a second method of manufacturing.

FIG. 7 is a top view depicting the structure of a twelfth example of the semiconductor module according to the embodiment.

FIG. 8A is a top view depicting the structure of a thirteenth example of the semiconductor module according to the embodiment.

FIG. 8B is a top view depicting the structure of a fourteenth example of the semiconductor module according to the embodiment.

FIG. 9 is a top view depicting the structure of a seventh comparison example with respect to the power semiconductor module according to the embodiment.

FIG. 10 is a top view depicting the structure of an eighth comparison example with respect to the power semiconductor module according to the embodiment.

FIG. 11 is a top view depicting the structure of a fifteenth example of the power semiconductor module according to the embodiment.

FIG. 12 is a top view depicting the structure of a sixteenth example of the power semiconductor module according to the embodiment.

FIG. 13 is a top view depicting the structure of a seventeenth example of the power semiconductor module according to the embodiment.

FIG. 14 is a cross-sectional view depicting a structure of a conventional power semiconductor module.

FIG. 15 is a cross-sectional view depicting a problem associated with the structure of the conventional power semiconductor module.

FIG. 16 is a top view depicting a problem occurring in the structure of the conventional power semiconductor module.

### DETAILED DESCRIPTION OF THE INVENTION

First, problems associated with conventional techniques are discussed. A conventional semiconductor device has a problem in that repeated thermal expansion and contraction causes thermal stress, which puts a load on the encapsulant (encapsulating resin), causing cracks in a portion of the resin directly above the chip, leading to module failure.

An outline of an embodiment of the present disclosure is described. A semiconductor module according to the present disclosure solving the problems described above and achieving an object has the following features. The semiconductor module includes a stacked substrate on which a semiconductor device is mounted via a bonding layer; an encapsulating resin that encapsulates encapsulated members, which include the semiconductor device, the bonding layer, and the stacked substrate; and a low elastic modulus region that is provided at a surface of the encapsulating resin above the semiconductor device, the low elastic modulus region having an elastic modulus that is lower than an elastic modulus of the encapsulating resin. A storage modulus of the low elastic modulus region is a relative elastic modulus of 0.83% or more but less than 100% when a storage modulus of the encapsulating resin is 100%.

According to the disclosure above, the low elastic modulus region having a low elastic modulus is provided at the surface of the encapsulating resin, directly above the power semiconductor chip where stress tends to concentrate and thus, stress is reduced and resin cracking may be suppressed.

Further, in the disclosure above, in the semiconductor module according to the present disclosure, the relative elastic modulus is in a range of 8% to 75%.

Further, in the disclosure above, in the semiconductor module according to the present disclosure, the relative elastic modulus is in a range of 25% to 50%.

Further, in the disclosure above, in the semiconductor module according to the present disclosure, the low elastic modulus region has a stripe-like shape extending parallel to a lateral direction of the semiconductor module in a top view.

Further, in the disclosure above, in the semiconductor module according to the present disclosure, the low elastic modulus region has a stipe-like shape extending parallel to a lateral direction of the semiconductor module and extending parallel to a longitudinal direction of the semiconductor module in a top view.

Further, in the disclosure above, in the semiconductor module according to the present disclosure, the low elastic modulus region is provided directly above the semiconductor device.

Further, in the disclosure above, in the semiconductor module according to the present disclosure, the low elastic modulus region has a bottom tip that is blunt and faces toward the semiconductor device.

Further, in the disclosure above, in the semiconductor module according to the present disclosure, the bottom tip has a curvature R that is 0.5 mm or more.

A method of manufacturing a semiconductor module according to the present disclosure solving the problems above and achieving an object has the following features. The method includes, as a first process, mounting a semiconductor device to a stacked substrate via a bonding layer; as a second process, encapsulating encapsulated members by a thermosetting resin composition, the encapsulated members including the semiconductor device, the bonding layer, and the stacked substrate; as a third process, injecting a low elasticity resin at a surface of the thermosetting resin composition above the semiconductor device, the low elasticity resin having an elastic modulus that is lower than an elastic modulus of the thermosetting resin composition; and as a fourth process, heating and curing the thermosetting resin composition and the low elasticity resin and thereby forming an encapsulating resin and a low elastic modulus region. The low elastic modulus region has an elastic modulus that is lower than an elastic modulus of the encapsulating resin.

Further, in the disclosure above, in the method of manufacturing the semiconductor module according to the present disclosure, a ratio of a viscosity of the thermosetting resin composition to a viscosity of the low elasticity resin in a range of 1:1 to 1:0.35 when a viscosity of the thermosetting resin composition is 1 is.

A method of manufacturing a semiconductor module according to the present disclosure solving the problems above and achieving an object has the following features. The method includes, as a first process, mounting a semiconductor device to a stacked substrate via a bonding layer; as a second process, encapsulating encapsulated members by a thermosetting resin composition, the encapsulated members including the semiconductor device, the bonding layer, and the stacked substrate; as a third process, inserting a low elastic modulus region that has been precured, the low elastic modulus region being inserted at a surface of the thermosetting resin composition above the semiconductor device; and as a fourth process, heating and curing the thermosetting resin composition and thereby forming an encapsulating resin. The low elastic modulus region has an elastic modulus that is lower than an elastic modulus of the encapsulating resin.

Findings underlying the present disclosure are discussed. Problems associated with a conventional semiconductor module are described. FIG. 14 is a cross-sectional view depicting a structure of a conventional power semiconductor module. As depicted in FIG. 14, a power semiconductor module 150 includes a power semiconductor chip 101, a stacked substrate 105, a case 107, a heat dissipation base 126, metal terminals 109, and metal wires 110. The power semiconductor chip 101 is a power semiconductor chip of, for example, a MOSFET, an IGBT, or a diode and is bonded on the stacked substrate 105 by a bonding layer 125 containing, for example, solder. In the stacked substrate 105, a first conductive plate 103 containing, for example, copper is provided on a front surface of an insulating substrate 102 such as a ceramic substrate and a second conductive plate 104 containing, for example, copper is provided at a back surface of the insulating substrate 102. The stacked substrate 105 is bonded to the heat dissipation base 126 by the bonding layer 125, which contains, for example, solder. The metal terminals 109, which carry signals to an external device, are bonded to the case 107. The metal wires 110 electrically connect the power semiconductor chip 101 and the metal terminals 109. Further, in an instance of a MOSFET, a source electrode pad is formed at a surface of the power semiconductor chip 101 as a power terminal electrode pad (current supply terminal). Further, a conductive connector member such as a lead frame or the metal wires 110 is disposed as an output terminal from a power terminal electrode pad. In an instance of a lead frame, the lead frame is bonded to the power semiconductor chip 101 by the bonding layer 125, which contains, for example, solder. While not depicted, these members are provided in plural in a single semiconductor module. The case 107 is adhered to the power semiconductor module 150, and a cover (not depicted) through which the metal terminals 109 penetrate and protrude externally is attached to the power semiconductor module 150. The case 107 is filled with an encapsulating resin (encapsulant) 108 that insulates and protects the stacked substrate 105 and the power semiconductor chips 101 on the substrate.

In particular, when, for example, an epoxy resin containing a filler such as silica is used as the encapsulating resin 108, which is hard (high elastic modulus), thermal deformation of circuit members may be mechanically suppressed while stress and damage of the circuit members are prevented, thereby achieving high reliability.

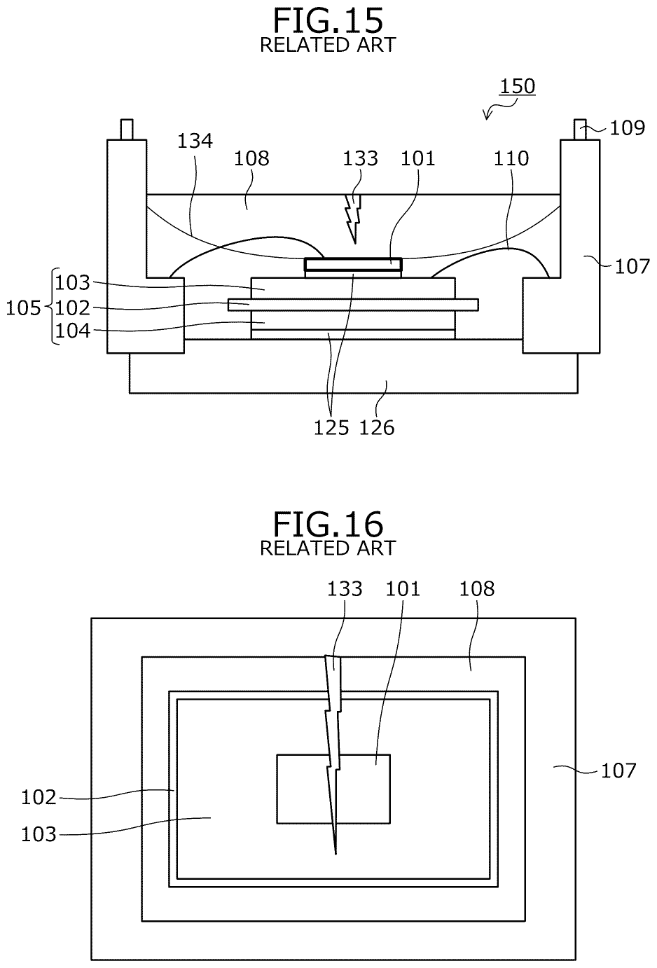

FIG. 15 is a cross-sectional view depicting a problem associated with the structure of the conventional power semiconductor module. FIG. 16 is a top view depicting a problem occurring in the structure of the conventional power semiconductor module. Operation of the power semiconductor module 150 causes the power semiconductor chip 101 to generate heat, whereby peripheral members such as the power semiconductor chip 101 and the insulating substrate 102 undergo thermal expansion, which generates thermal stress 134. In this instance, as depicted in FIGS. 15 and 16, the thermal stress 134, which is repeatedly generated by thermal expansion and contraction, stresses the encapsulating resin 108, thereby causing cracking 133 of the encapsulating resin 108 directly above the power semiconductor chip 101, which leads to module destruction. While a method of reducing the thermal stress 134 by lowering the elastic modulus of the encapsulating resin 108 prevents the occurrence of the cracking 133 of the encapsulating resin 108, a problem arises in that there a tradeoff between lowering the elastic modulus of the encapsulating resin 108 and the effect of preventing thermal deformation of circuit members. In addition, power semiconductor modules are often rectangular in shape in a top view and in this case, thermal stress particularly occurs along an axis passing through centers of the longitudinal sides and cracking may occur as depicted in FIG. 16.

Embodiments of a semiconductor module and a method of manufacturing a semiconductor module according to the present disclosure are described in detail with reference to the accompanying drawings. However, the present disclosure is not limited the embodiments.

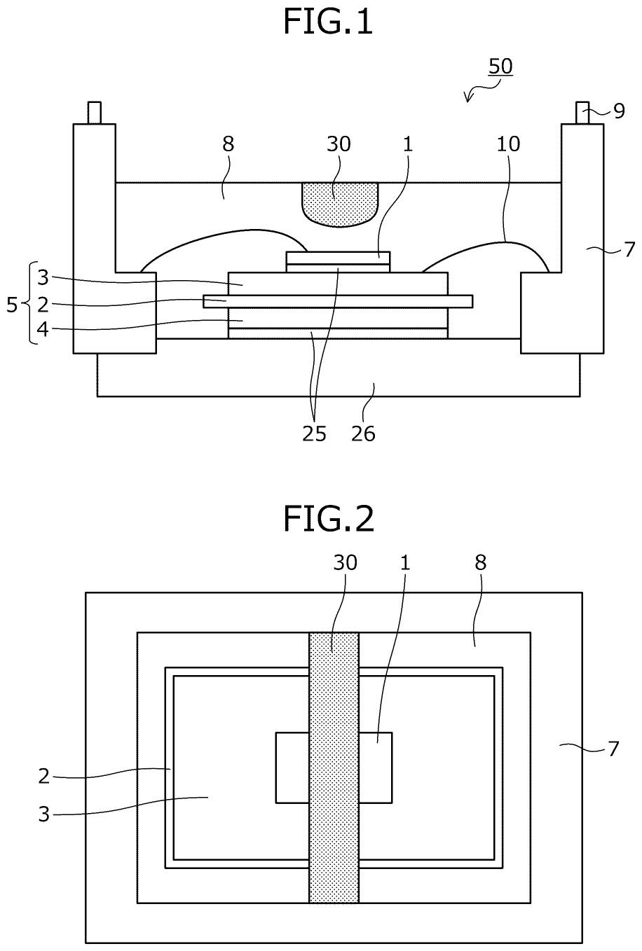

FIG. 1 is a cross-sectional view depicting configuration of a power semiconductor module according to an embodiment. In a power semiconductor module 50, an insulating substrate 2 has a front surface and a back surface opposite to each other, a first conductive plate 3 containing copper is provided at the front surface, and a second conductive plate 4 containing, for example, copper is provided at the back surface, thereby forming a stacked substrate 5. At a front surface of the stacked substrate 5 constituted by the first conductive plate 3, multiple power semiconductor chips 1 are mounted via bonding layers 25 that contain solder. Metal terminals 9, which lead out signals to external devices are bonded in a case 7. Further, at front surfaces (for example, source electrode pads) of the power semiconductor chips 1, conductive connector members such as pin-type terminals and lead frames are attached via metal wires (bonding wires) 10 such as aluminum wires and bonding layers (not depicted). Further, the power semiconductor chips 1 and the metal terminals 9 are electrically connected by the metal wires 10 such as aluminum wires or the like. A lead frame may be used (not depicted). A primer layer (not depicted) may be stacked on encapsulated members such as the power semiconductor chips 1, the stacked substrate 5, the bonding layers 25, and the metal wires 10 (conductive connector member) to enhance adhesion. Further, the case 7 is filled with an encapsulating resin 8. The depicted configuration of the power semiconductor module 50 is one example and the present invention is not limited to said configuration. Furthermore, the power semiconductor module has a substantially rectangular shape in a top view due to the components and while the power semiconductor module may have a substantially square-shape, substantially rectangular shapes are more frequently used.

The power semiconductor chips 1 are power chips of, for example, metal oxide semiconductor field effect transistors (MOSFETs), insulated gate bipolar transistors (IGBTs), or Schottky barrier diodes (SBDs) and devices employing semiconductor substrates containing Si, SiC, or GaN may be used. In particular, the present disclosure is effective for SiC chips and GaN chips that have high power and high Young's modulus. The number of the power semiconductor chips 1 mounted may be one or more.

A surface electrode (back electrode) at a back surface of each of the power semiconductor chips 1 is bonded to the first conductive plate 3, which constitutes the front surface of the stacked substrate 5, by one of the bonding layers 25, which contain, for example, solder. The second conductive plate 4 constituting the back surface of the stacked substrate 5 is bonded to a front surface of the heat dissipation base 26 by one of the bonding layers 25 containing, for example, solder. The first conductive plate 3 is formed by a predetermined circuit pattern at the front surface (first main surface) of the insulating substrate 2. The second conductive plate 4 may be a metal foil formed in an entire area of the back surface of the insulating substrate 2.

The stacked substrate 5 may be configured by the insulating substrate 2, the first conductive plate 3 formed in a predetermined shape at one main surface of the insulating substrate 2, and the second conductive plate 4 formed at the other main surface of the insulating substrate 2. A material having excellent electrical insulation and thermal conductivity may be used for the insulating substrate 2. A material of the insulating substrate 2 may be, for example, Al₂O₃, AlN, SiN, or the like. In particular, in high-voltage applications, a material that both electrically insulates and thermally conducts is preferable, and while AlN and SiN may be used, the material is not limited hereto. Copper (Cu) or a Cu alloy, which have excellent workability, may be used for the first conductive plate 3 and the second conductive plate 4. A Cu alloy is an alloy that contains at least 80% Cu. Among such conductive plates containing a Cu alloy or Cu, a conductive plate that is apart from the power semiconductor chips 1 may be referred to as a back surface foil or a back surface conductive plate. A method of providing conductive plates on the insulating substrate 2 may be, for example, a direct copper bonding method or an active metal brazing method. Further, nickel (Ni) plating or the like may be implemented at the surface of the conductive plates to thereby form a Ni or Ni alloy layer.

The heat dissipation base 26 is a heat sink having a substantially rectangular shape in a plan view and contains, for example, a metal such as Cu or Al, which have excellent thermal conductivity; the heat dissipation base 26 is also referred to as a metal substrate. A surface of the heat dissipation base 26 may be covered by a Ni film or a Ni alloy film to prevent corrosion. A back surface of the heat dissipation base 26 may be bonded to a cooling base part (not depicted). Heat is generated in the power semiconductor chips 1 and transmitted through the stacked substrate 5; and the heat dissipation base 26 conducts the heat to a heat dissipation fin part. The heat dissipation fin part has multiple heat dissipation fins and dissipates the heat conducted from the heat dissipation base 26. In addition, the heat dissipation base 26 itself may be a cooling device such as the heat dissipation fin part.

The bonding layers 25 may contain a lead-free solder. For example, while an Sn—Sb, Sn—Cu, Sn—Ag, or Sn—Sb—Ag based solder may be used, the bonding layers 25 are not limited hereto.

A lower end of the case 7, which is made of, for example, a resin, is adhered to a periphery of the heat dissipation base 26. The case 7 forms substantially a rectangular cylindrical shape and surrounds a periphery of the front surface of the heat dissipation base 26. A box-shaped recess is formed with the front surface of the heat dissipation base 26 as a bottom surface and inner walls of the case 7 perpendicular to the front surface of the heat dissipation base 26 as sidewalls. The recess houses the stacked substrate 5, the power semiconductor chips 1 wired by wiring members such as the metal wires 10 and lead frames, and the wiring members and components. A material of the case 7 may be, for example, a thermoplastic resin such as polyphenylene sulfide (PPS) and polybutylene terephthalate (PBT) or a thermosetting resin such as a phenolic resin. In addition, the semiconductor module may be formed without a case by molding the power semiconductor chips and the stacked substrate with encapsulating resin.

A primer layer (not depicted) may be formed on the encapsulated members. The primer layer may be a layer of a resin containing a polyamide, a polyimide, or a polyamideimide. Use of the primer layer may be advantageous because the primer layer may improve the adhesion at the interface of the encapsulating resin 8 and the conductive connector members such as the metal wires 10 and lead frames, the stacked substrate 5 (particularly, the first conductive plate 3, which constitutes a main surface), the heat dissipation base 26, and the case 7 (inner surface), whereby stress may be reduced. A thickness of the primer layer is not particularly limited as long as the thickness enables adhesion and relieves stress. The thickness of the primer layer may be, for example, in a range of about 1 μm to 15 μm and preferably, may be in a range of 2 μm to 10 μm. The primer layer may be provided so as to cover the entire surface of the components above. Such primer layers are prone to moisture absorption, which may reduce adhesion. The power semiconductor module may be free of a primer layer.

The encapsulating resin 8 is used as an encapsulating resin layer that encapsulates the encapsulated members and is provided in contact with the primer layer, or when the power semiconductor module does not have a primer layer (not shown), the encapsulating resin 8 is provided in contact with the encapsulated members and mainly covers the periphery of the power semiconductor chips 1, the stacked substrate 5, the metal wires 10, the lead frame, etc. The encapsulating resin 8 may contain a thermosetting resin composition and preferably may contain a highly heat-resistant thermosetting resin composition. The thermosetting resin composition contains a thermosetting resin base agent and may contain an inorganic filler, a curing agent, a curing accelerator, and necessary additives arbitrarily selected. While the thermosetting resin composition of the encapsulating resin 8 may or may not contain a fluorine-based silane coupling agent, it preferable for the thermosetting resin composition to be free of a fluorine-based silane coupling agent. A reason for this is that the glass transition temperature (Tg) of the encapsulating resin 8 may be lowered.

Examples of the thermosetting resin base agent include, but are not limited to, for example, epoxy resins, phenolic resins, maleimide resins, and the like. Among these, an epoxy resin having at least two epoxy groups in one molecule is particularly preferrable due to high dimensional stability, water resistance, chemical resistance, and electrical insulation. In particular, use of an aliphatic epoxy resin, an alicyclic epoxy resin, or a mixture of these is preferable.

An aliphatic epoxy resin is an epoxy compound in which the carbon to which the epoxy group is directly bonded constitutes an aliphatic hydrocarbon. Thus, even when a compound contains an aromatic ring in the main skeletal structure, if the compound meets the above conditions, the compound is classified as an aliphatic epoxy resin. Aliphatic epoxy resins include, but are not limited to, bisphenol A type epoxy resins, bisphenol F type epoxy resins, bisphenol AD type epoxy resins, biphenyl type epoxy resins, naphthalene type epoxy resins, cresol novolac type epoxy resins, and multifunctional epoxy resins with three or more functional groups. These may be used alone or in a combination of two or more. Further, naphthalene-type epoxy resins and multifunctional epoxy resins with three or more functionalities have a high glass transition temperature and thus, are also called high heat-resistant epoxy resins. Inclusion of these high heat-resistant epoxy resins may improve heat resistance.

Alicyclic epoxy resin refers to an epoxy compound in which the two carbon atoms that make up the epoxy group form an alicyclic compound. Alicyclic epoxy resins include, but are not limited to, monofunctional epoxy resins, bifunctional epoxy resins, and multifunctional epoxy resins with three or more functional groups. Alicyclic epoxy resins may also be used alone or in a combination with two or more different alicyclic epoxy resins. In addition, when an alicyclic epoxy resin is mixed with an acid anhydride curing agent and cured, the glass transition temperature increases and thus, mixing an alicyclic epoxy resin with an aliphatic epoxy resin may improve heat resistance.

The thermosetting resin base agent used in the composition of the present embodiment may be a mixture of the above-mentioned aliphatic epoxy resin and alicyclic epoxy resin. A mixing ratio may be arbitrary; a mass ratio of the aliphatic epoxy resin to the alicyclic epoxy resin may be about 2:8 to 8:2 or may be about 3:7 to 7:3 and is not limited to a specific mass ratio. Preferably, the thermosetting resin base agent may have a mass ratio of bisphenol A-type epoxy resin to alicyclic epoxy resin in a range of 1:1 to 1:4.

The thermosetting resin composition according to the present embodiment may contain an inorganic filler (filler) as an optional component. The inorganic filler may be a metal oxide or a metal nitride such as but not limited to, for example, fused silica (fused silicon oxide), silica (silicon oxide), alumina (aluminum oxide), aluminum hydroxide, titania (titanium dioxide), zirconia (zirconium oxide), aluminum nitride, talc, clay, mica, glass fibers, and the like. These inorganic fillers may increase the thermal conductivity of the cured material and reduce the thermal expansion rate. Further, these inorganic fillers may be used alone or in a combination of two or more. Furthermore, these inorganic fillers may be microfillers or nanofillers, and two or more types of inorganic fillers of different particle sizes and/or types may be used in combination.

The thermosetting resin composition may contain, as an optional component, a curing agent in addition to the thermosetting resin base agent, or in addition to the thermosetting resin base agent and the inorganic filler. While the curing agent is not particularly limited as long as the curing agent reacts with the thermosetting resin base agent (preferably an epoxy resin base agent) and can be cured, preferably, an acid anhydride curing agent may be used. Examples of acid anhydride curing agents include aromatic acid anhydrides, specifically phthalic anhydride, pyromellitic anhydride, trimellitic anhydride, and the like. Alternative examples include cycloaliphatic acid anhydrides, specifically tetrahydrophthalic anhydride, methyltetrahydrophthalic anhydride, hexahydrophthalic anhydride, methylhexahydrophthalic anhydride, methylnadic anhydride, etc., or aliphatic acid anhydrides, specifically succinic anhydride, polyadipic anhydride, polysebacic anhydride, polyazelaic anhydride, and the like. In addition, when a bisphenol A type epoxy resin is used alone or a mixture of a bisphenol A type epoxy resin and the previously mentioned high heat-resistant epoxy resin is used as a thermosetting resin base agent, it may be preferable not to use a curing agent because heat resistance is improved.

The thermosetting resin composition may further optionally contain, as an optional component, a curing accelerator. As the curing accelerator, imidazole or its derivatives, tertiary amines, boric acid esters, Lewis acids, organometallic compounds, organic acid metal salts, or the like may be suitably added.

The thermosetting resin composition may further contain optional additives, provided the additives do not impair the properties of the thermosetting resin composition. Examples of additives include, but are not limited to, flame retardants, pigments to color resins, plasticizers and silicone elastomers to improve crack resistance. These optional components and the added amount thereof may be suitably determined according the specifications necessary for the semiconductor module and/or encapsulant by one skilled in the art. The elastic modulus of the thermosetting resin composition (cured product) containing the inorganic filler described above and whose thermosetting resin base agent is an epoxy resin may be set in a range of 10 GPa to 20 GPa or preferably in a range of 11 GPa to 13 GPa, as the storage modulus. In addition, the encapsulating resin 8 is an organosilicon polymer whose main chain is composed of siloxane bonds; and may be a silicone resin (silicone gel) with an elastic modulus of 100 MPa or less and a penetration (1/mm) of 0.1 to 500.

In the power semiconductor module 50 of the embodiment, a low elastic modulus region (a low-elastic-modulus element) 30 having a low elastic modulus is provided at the surface of the encapsulating resin 8 where resin cracking tends to occur. The low elastic modulus region 30 is provided directly above the power semiconductor chips 1 where stress tends to concentrate, whereby stress is reduced and resin cracking may be suppressed.

FIG. 2 is a top view depicting the structure of the power semiconductor module according to the embodiment. As depicted in FIG. 2, preferably, the low elastic modulus region 30 may be provided in a stripe-like shape parallel to the direction (lateral direction of the power semiconductor module 50) in which resin cracking emerges. In FIG. 2, while the low elastic modulus region 30 is formed so as to connect longitudinal inner walls of the case, the low elastic modulus region 30 may be provided near a center portion without being in contact with the inner walls of the case or may be provided near a center portion in the longitudinal direction of the power semiconductor module, in a top view.

The low elastic modulus region 30 of the embodiment has a storage modulus that is lower than a storage modulus of the encapsulating resin 8. While described in detail in experimental examples hereinafter, the storage modulus of the low elastic modulus region 30 when the storage modulus of the encapsulating resin 8 is 100% is referred to as a relative elastic modulus and when the relative elastic modulus is 0.83% or higher but less than 100%, the P/C capability is enhanced. Further, when the relative elastic modulus is in a range of 8% to 75%, the P/C capability increases 20% or more and thus, is more preferable. Moreover, when the relative elastic modulus is in a range of 25% to 50%, the P/C capability increases 30% or more and thus, is preferable.

While described in detail in the experimental examples hereinafter, as depicted in FIG. 1, a portion of the low elastic modulus region 30 in contact with the encapsulating resin 8 has a curved shape with a tip (bottom tip) that is not sharp (blunt), in cross-sectional view. For example, for shapes that do not include a straight part, such as a semicircle or a semi-ellipse, or for shapes that include a straight part, such as a half-moon shape or a semicylindrical shape, the tip (bottom tip) preferably has a curvature R of at least R=0.5 mm. Further, the shape of a portion (portion exposed at the module surface) not in contact with the encapsulating resin 8 is not particularly specified.

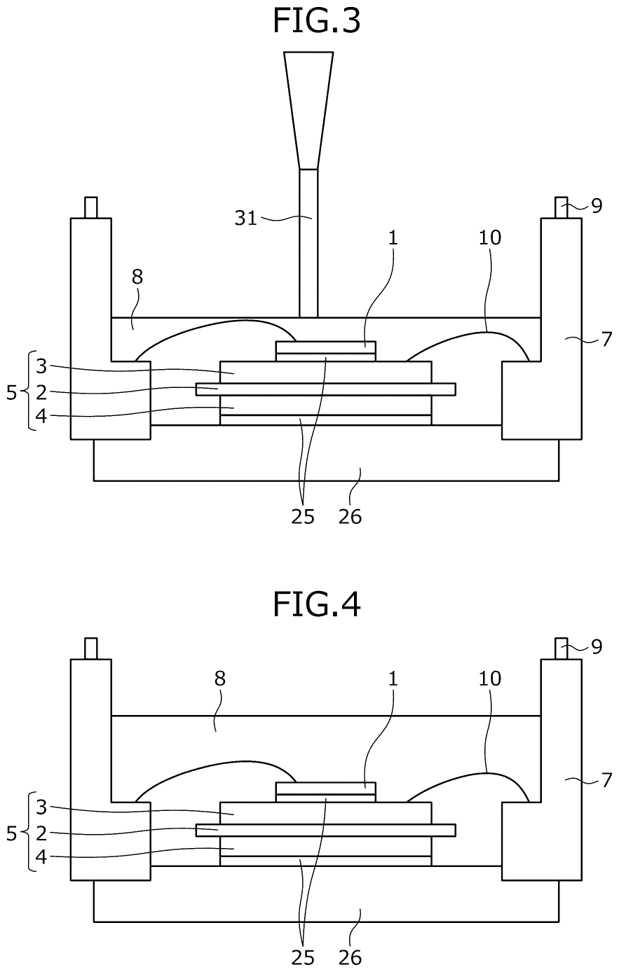

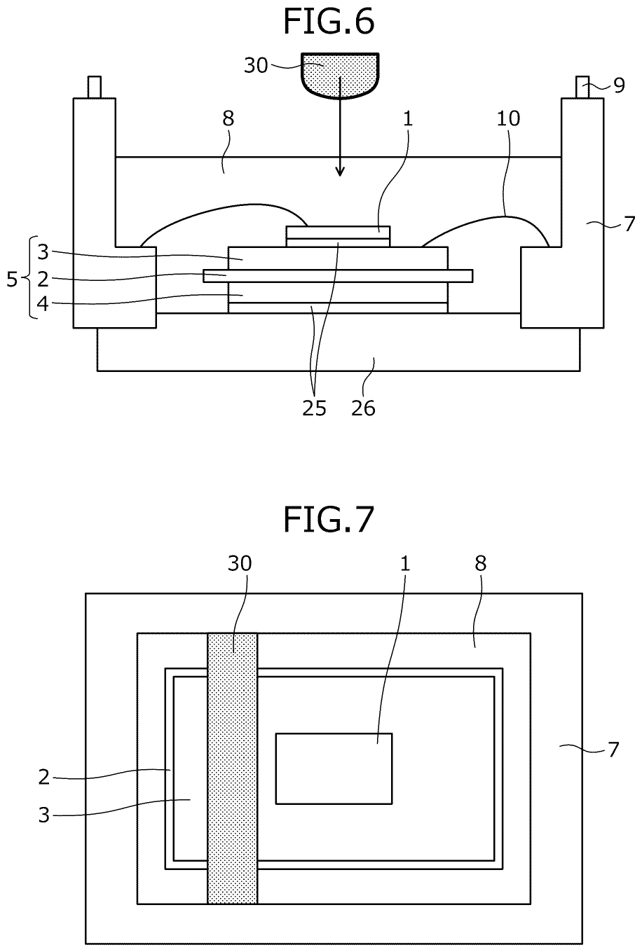

Next, a method of manufacturing the power semiconductor module according to the embodiment is described. FIGS. 3, 4, and 5 are cross-sectional views schematically depicting states of the power semiconductor module according to the embodiment during manufacture according to the first method of manufacturing. FIG. 6 is a cross-sectional view schematically depicting a state of the power semiconductor module according to the embodiment during manufacture according to a second method of manufacturing. In the first method of manufacturing and the second method of manufacturing, first, the power semiconductor chips 1 are bonded to the heat dissipation base 26 and the stacked substrate 5 by the bonding layers 25.

Thereafter, the case 7 is attached to the heat dissipation base 26 and thereafter, lead frames are bonded and wire bonding is performed with the metal wires 10. In addition, instead of the lead frames, the metal wires 10 may be used. Next, a primer layer may be formed. The primer layer may be provided to the power semiconductor chips 1, the stacked substrate 5, the lead frames, the metal wires 10, and the case 7 by, for example, a spraying application. After the primer layer is formed, heating at a temperature of 70 degrees C. to 90 degrees C. for 60 minutes to 80 minutes in an inert oven containing nitrogen gas and further heating at a temperature of 200 degrees C. to 220 degrees C. for 60 minutes to 80 minutes is preferable. This heating treatment suppresses oxidation of Cu surfaces, heats Cu contained in the lead frames, advances the reaction of the primer layer and Cu, and may enhance adhesion between the primer layer and the lead frames. In addition, in the present embodiment, the power semiconductor module 50 may be free of a primer layer and in this instance, the spraying application and the heating treatment in the inert oven may be omitted.

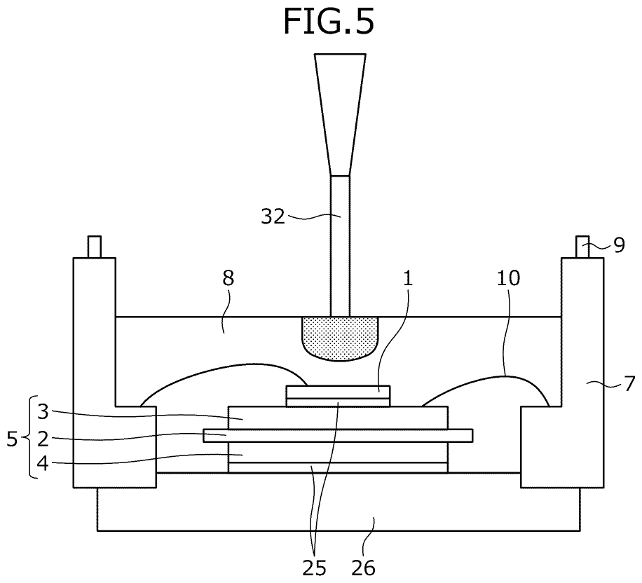

Next, in the first method of manufacturing, as depicted in FIG. 3, a melted thermosetting resin composition 31 constituting the encapsulating resin 8 is injected into the case 7. A state of injecting the thermosetting resin composition 31 is depicted in FIG. 4. Next, as depicted in FIG. 5, a low elasticity resin 32 is injected into a portion. Here, the low elasticity resin 32 has a high viscosity and thus, rarely diffuses spontaneously into the encapsulating resin. Thereafter, the thermosetting resin composition 31 and the low elasticity resin 32 are heated and cured thereby forming the encapsulating resin 8 and the low elastic modulus region 30. For example, the power semiconductor module 50 depicted in FIG. 1 is manufactured by performing a precuring treatment at a temperature in a range of 100 degrees C. to 120 degrees C. for 10 minutes to 120 minutes and a main curing treatment at a temperature in a range of about 175 degrees C. to 185 degrees C. for 1 hour to 2 hours.

Further, in the second method of manufacturing, similar to the first method of manufacturing, the melted thermosetting resin composition 31 constituting the encapsulating resin 8 is injected into a portion of the case 7 (refer to FIG. 3). A state of injecting the thermosetting resin composition 31 is a same as the state in the first method of manufacturing (refer to FIG. 4). Next, as depicted in FIG. 6, the low elastic modulus region 30 constituted by the low elasticity resin 32 that has been precured is inserted into the thermosetting resin composition 31, which has been precured or is free of curing. Thereafter, the thermosetting resin composition 31 is heated and cured. For example, the power semiconductor module 50 depicted in FIG. 1 is manufactured by performing a precuring treatment at a temperature in a range of 100 degrees C. to 120 degrees C. for 10 minutes to 120 minutes and a main curing treatment at a temperature in a range of about 175 degrees C. to 185 degrees C. for 1 hour to 2 hours.

Here, the present disclosure is described in detail with reference to the experimental examples and examples of the present disclosure. However, the present disclosure is not limited to the experimental example or the examples below. In a first experimental example, an experiment related to low elasticity materials used for the low elastic modulus region 30 was performed. In second and third experimental examples, experiments related to positioning of the low elastic modulus region 30 were performed. In a fourth experimental example, an experiment related to a cross-sectional shape of the low elastic modulus region 30 was performed. In a fifth experimental example, an experiment related to a range of viscosity of a first method of manufacturing was performed. In a sixth experimental example, an experiment related to a method of fabrication was performed.

In the first experimental example, power cycling (P/C) capability in instances in which the low elastic modulus region 30 has various storage moduli were compared with the encapsulating resin 8 for which the storage modulus was 12 GPa at 25 degrees C. after curing. Results are shown in Table 1. In Table 1, “X” indicates that the elastic modulus was not measurable by DMS described hereinafter and penetration was 35.

TABLE 1

| | | RELATIVE ELASTIC MODULUS | | |
|---|---|---|---|---|
| | STORAGE | (WHEN ELASTIC MODULUS | | |
| EXAMPLE/ | MODULUS OF LOW | OF ENCAPUSULATING | | P/C |
| COMPARISON | ELASTICITY RESIN | RESIN IS 100% | | CAPABILITY |
| EXAMPLE | GPa | % | RESIN | kcyc. |
| FIRST COMPARISON | 12 (ENCAPUSALTING | 100 | EPOXY RESIN A (FILLER 73 wt %) | 70 |
| EXAMPLE | RESIN LAYER) NO | | | |
| | LOW ELASTIC | | | |
| | MODULUS REGION | | | |
| SECOND COMPARISON | 14 | 117 | EPOXY RESIN A (FILLER 90 wt %) | 70 |
| EXAMPLE | | | | |
| THIRD COMPARISON | 13 | 108 | EPOXY RESIN A (FILLER 80 wt %) | 70 |
| EXAMPLE | | | | |
| FOURTH COMPARISON | — | — | ONLY RECESS PROVIDED, NO | 65 |
| EXAMPLE | | | LOW ELASTICITY MATERIAL | |
| FIFTH COMPARISON | 0.01 | 0.083 | SILICONE RUBBER B 100% | 70 |
| EXAMPLE | | | | |
| SIXTH COMPARISON | □ | □ | SILICONE GEL | 65 |
| EXAMPLE | | | | |
| FIRST EXAMPLE | 11 | 92 | EPOXY RESIN A (FILLER 60 wt %) | 75 |
| SECOND EXAMPLE | 10 | 83 | EPOXY RESIN A (FILLER 50 wt %) | 80 |
| THIRD EXAMPLE | 9 | 75 | EPOXY RESIN A (FILLER 35 wt %) | 90 |
| FOURTH EXAMPLE | 7.5 | 63 | EPOXY RESIN A (FILLER 20 wt %) | 95 |
| FIFTH EXAMPLE | 6 | 50 | EPOXY RESIN A (NO FILLER) | 105 |
| SIXTH EXAMPLE | 3 | 25 | EPOXY RESIN A (NO FILLER) + | 100 |
| | | | SILICONE RUBBER A | |
| | | | (10 wt % ADDED) | |
| SEVENTH EXAMPLE | 1 | 8 | EPOXY RESIN A (NO FILLER) + | 90 |
| | | | SILICONE RUBBER A | |
| | | | (20 wt % ADDED) | |
| EIGHTH EXAMPLE | 0.5 | 4.2 | EPOXY RESIN A (NO FILLER) + | 80 |
| | | | SILICONE RUBBER A | |
| | | | (35 wt % ADDED) | |
| NINTH EXAMPLE | 0.1 | 0.83 | SILICONE RUBBER A 100% | 75 |

The low elasticity resins used had a storage modulus of 6 GPa or more, up to 14 GPa, and were prepared by adjusting the elastic modulus by increasing or decreasing the filler concentration from a standard filler concentration of 73 wt %, using a normal encapsulating resin (an epoxy resin A (mixture of a bisphenol A-type and an alicyclic epoxy)) with a storage modulus of 12 GPa (first to fifth examples, first to third comparison examples). In addition to the epoxy resin, silicone rubber was added to a material having a storage modulus of 3 GPa to adjust the storage modulus (sixth to eighth examples). Alternatively, the silicone rubber material itself and a silicone gel were used (ninth example, fifth and sixth comparison examples). Further, to confirm the effect of the shape of the low elastic modulus region 30 itself, an example (comparative example 4) was also prepared in which a recess was provided in the low elastic modulus region 30 but nothing was encapsulated in the low elasticity material.

Details of the first example are shown below. 1) Test module Epoxy Resin ME-276 (manufactured by Pelnox, Ltd.) was used as the epoxy resin of the encapsulating resin 8; and MV-138 (manufactured by Pelnox, Ltd.) was added at 121 parts by mass per 100 parts by mass of epoxy resin, as an acid anhydride curing agent. As the filler, spherical silica having an average particle diameter of 10 μm (manufactured by AGC Inc.) was used, and 270 parts by mass was added assuming the total mass of the epoxy resin and the curing agent was 100 parts by mass. At this time, the filler concentration was 73 wt %.

2) Low elastic modulus region 30
Material: As the epoxy resin A, Epoxy Resin ME-276 (manufactured by Pelnox, Ltd.)
   was used as a main agent and MV-138 (manufactured by Pelnox, Ltd.) was used as a curing agent, similar to the material of the encapsulating resin 8 above. The filler was also spherical silica (manufactured by AGC Inc.) with an average particle size of 10 μm, but the amount added was 150 parts by mass, assuming the total mass of the main agent and the curing agent of the epoxy resin was 100 parts by mass. As a result, the filler concentration was 60 wt %.
Shape, arrangement

The low elastic modulus region 30 had a half-moon shape in a cross-sectional view as depicted in FIG. 1 and was provided directly above the power semiconductor chips 1 in a direction parallel to the lateral sides of the module as depicted in FIG. 2; the method of fabrication used was the first method of manufacturing (in the first method of manufacturing, the low elasticity resin was fabricated by casting the resin at a low viscosity resin temperature of 20 degrees C. and an encapsulating resin temperature of 60 degrees C. so that the resin viscosity difference was 1:0.5, followed by thermal curing).

In particular, the low elastic modulus region 30 had a half-moon shape with a depth of 3 mm (20% or more of the thickness of the encapsulating resin 8, for example, 10 mm) and a width of 5 mm (about the size of one of the power semiconductor chips 1 (elements), about 50% to 150% of the width of each of the elements). The size of the encapsulating resin 8 of the power semiconductor module 50, as viewed from above, was 50 mm in the lateral direction and 70 mm in the longitudinal direction, and a maximum thickness of the encapsulating resin 8 was 10 mm.

### 3) Method of Evaluation

Storage modulus evaluation

The storage modulus of a resin sample molded into a plate shape of 50×10×2.0 mm³ was measured using a dynamic viscoelasticity measuring device (DMS), in a double-support beam measurement mode. The measurement was performed at room temperature, with an applied frequency of 1 Hz and a measurement length of 20 mm.
Evaluation of reliability

The P/C test was performed by applying electricity so that the temperature reached 175 degrees C. from 40 degrees C., with one cycle consisting of 2 seconds of operation and 9 seconds of rest, and the number of cycles free of abnormalities in the electrical properties due to the progression of cracks at the resin surface was recorded.

Details of second, third, fourth, fifth, sixth, seventh, eighth, and ninth examples are shown below. In the second to ninth examples, as depicted in Table 1, other than changing the material of the low elastic modulus region 30, changing the storage modulus, and changing the relative elastic modulus from 8.3% to 100%, modules were fabricated by the same method and conditions of the first example and reliability of the modules was evaluated. In particular, in the second to fifth examples, the filler concentration of the first example was changed to the amounts indicated in Table 1. Further, in the sixth to ninth examples, with respect to the fifth example, KE-66 (manufactured by Shin-Etsu Chemical Co., Ltd.), which is a 2-component silicone rubber was added as a silicone rubber A in the amounts indicated in Table 1.

Details of first, second, third, fourth, fifth, and sixth comparison examples are shown below. As depicted in Table 1, in the first to third comparison examples, other than using a material having a larger storage modulus than the storage modulus of the encapsulating resin 8 in the low elastic modulus region 30, a module was fabricated by the same method and conditions of the first example and the reliability of the module was evaluated. In particular, in the first to third comparison examples, the filler concentration of the first example was set to the filler concentration shown in Table 1. Further, in the fourth comparison example, other than providing a recess and nothing being encapsulated in the low elastic modulus region 30, the module was fabricated by the same method and conditions of the first example and the reliability of the module was evaluated. Further, in the fifth comparison example, instead of the silicone rubber A of the ninth example, KE-1031 (manufactured by Shin-Etsu Chemical Co., Ltd.), which is a 2-component silicone rubber, was used as a silicone rubber B. Further, in the sixth comparison example, a silicone gel was used. For the silicone gel, TSE3051FH, which is a 1-compoent silicone gel manufactured by Momentive Performance Materials, was used and cured under the conditions of 80 degrees C. for 30 minutes. In addition, the silicone gel (after curing) was too soft to measure in the method of evaluating the storage modulus above and penetration was 35. Furthermore, penetration is a method for measuring the hardness of a material, in which a conical needle of a given weight is dropped vertically onto an object to be measured and the extent to which the needle sinks is evaluated in units of 1/10 mm. In this instance, the penetration depth was measured when the needle was inserted for 5 seconds under the conditions specified in ASTM D-1403.

As a result, when the storage modulus of the low elastic modulus region 30 is assumed to be a relative elastic modulus when the storage modulus of the encapsulating resin 8 is assumed to be 100%, the P/C capability improves when the relative elastic modulus is 0.83% or higher but less than 100%. Further, when the relative elastic modulus is in a range of 4.2% to 83%, the P/C capability improves 14% or more and thus, is preferable; furthermore, when the relative elastic modulus is in a range of 8% to 75%, the P/C capability improves 25% or more and thus, is preferable. Moreover, when the relative elastic modulus is in a range of 25% to 50%, the P/C capability improves 40% or more and thus, is further preferable.

On the other hand, when the relative elastic modulus decreased below 0.83%, the effect of improving the P/C capability by the low elasticity disappeared and when the relative elastic modulus was also low at 0.083% or less, the P/C capability was slightly worse than in the first comparison example.

The second experimental example confirmed the effect of providing the low elastic modulus region 30 directly above the power semiconductor chips 1 or at a location other than directly above the power semiconductor chips 1. The results are shown in Table 2. FIG. 7 is a top view depicting the structure of a twelfth example of the semiconductor module according to the embodiment. The structure of the fifth example is a same as the structure of the first example of the first experimental example. The structure of the first comparison example is a same as the structure of the first comparison example of the first experimental example. In addition, “directly above” further includes instances in which a portion of the low elastic modulus region 30 partially overlaps the power semiconductor chips in a plan view.

TABLE 2

| | | EXAMPLE/COMPARISON EXAMPLE | | |
|---|---|---|---|---|
| | | FIRST | | |
| | | COMPARISON | FIFTH | TWELFTH |
| | | EXAMPLE | EXAMPLE | EXAMPLE |
| POSITION OF | | NOT PROVIDED | DIRECTLY | OTHER |
| LOW ELASTIC | | (COMPARISON | ABOVE | THAN |
| MODULUS | | EXAMPLE) | CHIP | DIRECTLY |
| REGION | | | | ABOVE |
| | | | | CHIP |
| P/C | kcyc. | 70 | 105 | 90 |
| TOLERANCE | | | | |
| UNTIL RESIN | | | | |
| CRACKS | | | | |

In the fifth example, in the low elastic modulus region 30, a resin with a storage modulus of 6 GPa was used and provided directly above the power semiconductor chips 1, extending in a direction parallel to the lateral sides of the module as depicted in FIG. 1 and the method of fabrication was the first method of manufacturing. In the twelfth example, in the low elastic modulus region 30, the same resin as that in the fifth example was used and was provided at a location other than directly above the power semiconductor chips 1, extending in a direction parallel to the lateral sides of the module as depicted in FIG. 7 and the method of fabrication was the first method of manufacturing.

In particular, within a range of +10% (+7 mm) from the center of the power semiconductor chips 1 as a reference point is defined to be “directly above the power semiconductor chips 1” while beyond the range of ±10% (±7 mm) is defined to be “a location other than directly above the power semiconductor chips 1”. From the results, it was confirmed that providing the low elastic modulus region 30 directly above the power semiconductor chips 1 or at a location other than directly above the power semiconductor chips 1 improved tolerance against resin cracking during P/C. At this time, it was found that providing the low elastic modulus region directly above the power semiconductor chips 1 more effectively improved the tolerance against resin cracking during P/C. In addition, in the present experimental example, while verification was performed by arranging a power semiconductor chip nearly in a center of encapsulating resin in a plan view, even in an instance in which multiple power semiconductor chips are arranged not only in the center, effects similar to those of the present experimental example were obtained when the low elastic modulus region 30 was disposed directly above the power semiconductor chips.

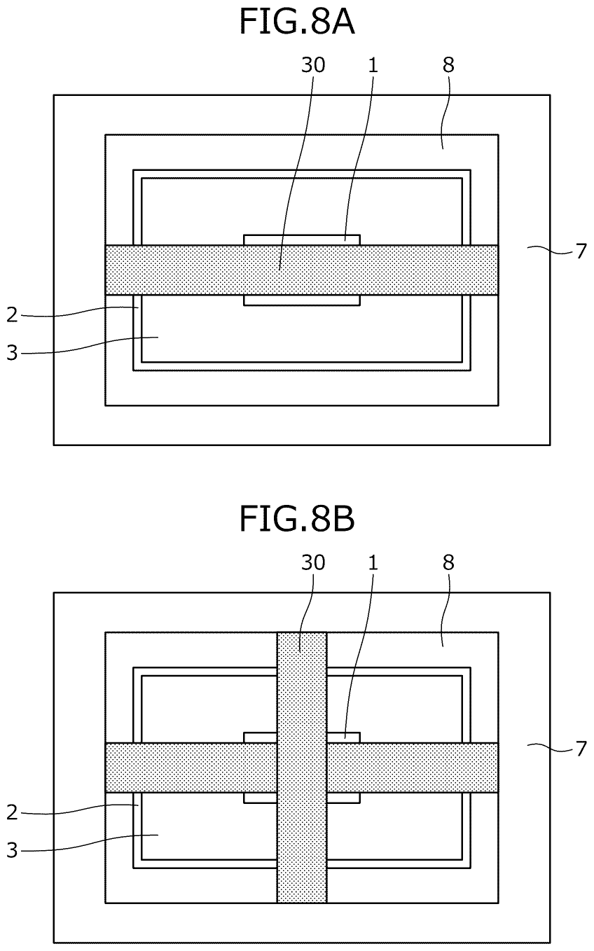

In the third experimental example, effects of providing the low elastic modulus region 30 extending in the lateral direction and/or the longitudinal direction of the module were confirmed. The results are shown in Table 3. FIG. 8A is a top view depicting the structure of a thirteenth example of the semiconductor module according to the embodiment. FIG. 8B is a top view depicting the structure of a fourteenth example of the semiconductor module according to the embodiment. The structure of the fifth example is a same as the structure of the first example of the first experimental example. The structure of the first comparison example is a same as the structure of the first comparison example of the first experimental example.

TABLE 3

| | | EXAMPLE/COMPARISON EXAMPLE | | | |
|---|---|---|---|---|---|
| | | FIRST | | | |
| | | COMPARISON | FIFTH | THIRTEENTH | FOURTEENTH |
| | | EXAMPLE | EXAMPLE | EXAMPLE | EXAMPLE |
| ORIENTATION OF | | NOT PROVIDED | PARALLEL TO | PARALLEL TO | PARALLEL TO |
| LOW ELASTIC | | | LATERAL SIDES | LONGITUDINAL | LATERAL SIDES |
| MODULUS REGION | | | | SIDES | AND PARALLEL TO |
| | | | | | LONGITUDINAL |
| | | | | | SIDES |
| P/C TOLERANCE | kcyc. | 70 | 105 | 80 | 110 |
| UNTIL RESIN | | | | | |
| CRACKS | | | | | |

In the fifth example, in the low elastic modulus region 30, a resin with a storage modulus of 6 GPa was used and provided directly above the power semiconductor chips 1, extending in a direction parallel to the lateral sides of the module as depicted in FIG. 2 and the method of fabrication was the first method of manufacturing. In the thirteenth example, in the low elastic modulus region 30, a resin with a storage modulus of 6 GPa was used and provided directly above the power semiconductor chips 1, extending in a direction parallel to the longitudinal sides of the module as depicted in FIG. 8A and the method of fabrication was the first method of manufacturing. In the fourteenth example, in the low elastic modulus region 30, a resin with a storage modulus of 6 GPa was used and provided directly above the power semiconductor chips 1, extending in a direction parallel to the longitudinal sides of the module and in a direction parallel to the lateral sides of the module as depicted in FIG. 8B, and the method of fabrication was the first method of manufacturing.

In the fifth, thirteenth, and fourteenth examples, while the results confirmed that the P/C capability improved in all of the comparison examples thereof, the effect of improving the P/C capability was remarkable when the low elastic modulus region 30 was disposed in a direction parallel to the lateral sides in the fifth and fourteenth examples. Further, the effect of improving the P/C capability was the most remarkable when the low elastic modulus region 30 was disposed in a direction parallel to the lateral sides and a direction parallel to the longitudinal sides in the fourteenth example.

In the fourth experimental example, the effects were confirmed when, in a cross-sectional view, the shape of the low elastic modulus region 30 with a depth of 3 mm and a width of 5 mm had a half-moon shape, a rectangular shape, an inverted triangular shape, a rectangular shape (with curvature R, R=0.5 mm), and an inverted triangular shape (with curvature R, R=0.5 mm). A half-moon shape refers to a shape that does not contain any linear segments in a curved portion, such as a semicircle or semi-ellipse. The results are shown in Table 4.

TABLE 4

| EXAMPLE/ | | FIRST | SEVENTH | EIGHTH | | | |
|---|---|---|---|---|---|---|---|
| COMPARISON | | COMPARISON | COMPARISON | COMPARISON | FIFTEENTH | SIXTEENTH | SEVENTEENTH |
| EXAMPLE | | EXAMPLE | EXAMPLE | EXAMPLE | EXAMPLE | EXAMPLE | EXAMPLE |
| CROSS-SECTIONAL | | NOT | RECTANGLE | INVERTED | HALF-MOON | RECTANGLE | INVERTED |
| SHAPE OF LOW | | PROVIDED | | TRIANGLE | | (WITH R) | TRIANGLE |
| ELASTIC MODULUS | | | | | | | (WITH R) |
| REGION | | | | | | | |
| CURVATURE R (mm) | | — | (0.25) | (0.25) | □ | 0.5 | 0.5 |
| P/C TOLERANCE | kcyc. | 70 | 65 | 65 | 95 | 90 | 85 |
| UNTIL RESIN CRACKS | | | | | | | |

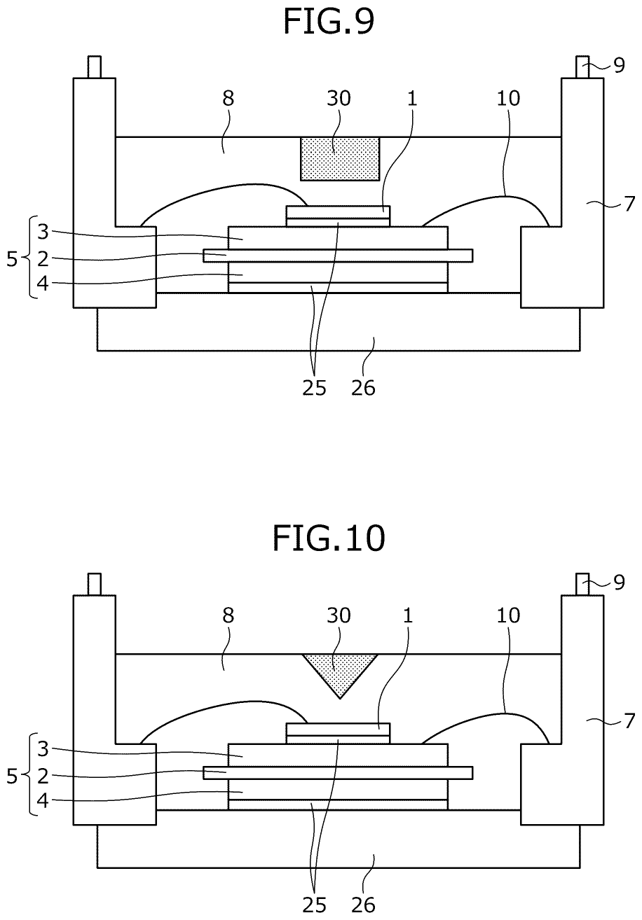

The structure of the first comparison example of the fourth experimental example is a same as the structure of the first comparison example of the first experimental example. In the seventh comparison example, a rectangular shape was used. FIG. 9 is a top view depicting the structure of the seventh comparison example with respect to the power semiconductor module according to the embodiment. The storage modulus, the position, the method of fabrication, etc. were the same as those of a fifteenth example. In the eighth comparison example, an inverted triangular shape was used. FIG. 10 is a top view depicting the structure of the eighth comparison example with respect to the power semiconductor module according to the embodiment. The storage modulus, the position, the method of fabrication, etc. were the same as those of the fifteenth example. In addition, as for rectangles and inverted triangles, vertices thereof intentionally not given curvature R were assumed to have a curvature R of about 0.25 for the sake of simplicity.

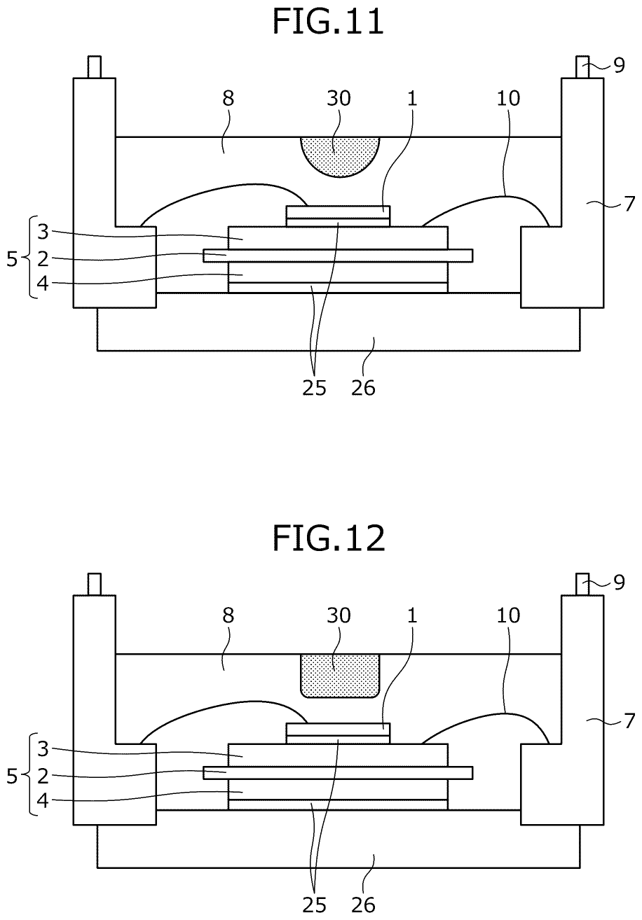

In the fifteenth example, a half-moon shape was used. FIG. 11 is a top view depicting the structure of the fifteenth example of the power semiconductor module according to the embodiment. In the fifteenth example, a semi-elliptical shape with a minor radius of 1.5 mm and a major radius of 2.5 mm was used. In the low elastic modulus region 30, resin with a storage modulus of 6 GPa was used, the low elastic modulus region 30 was provided so as to pass directly above the power semiconductor chips 1, and the method of fabrication was the second method of manufacturing. In addition, the low elastic modulus region 30 was fabricated by injecting a predetermined material into a mold in advance.

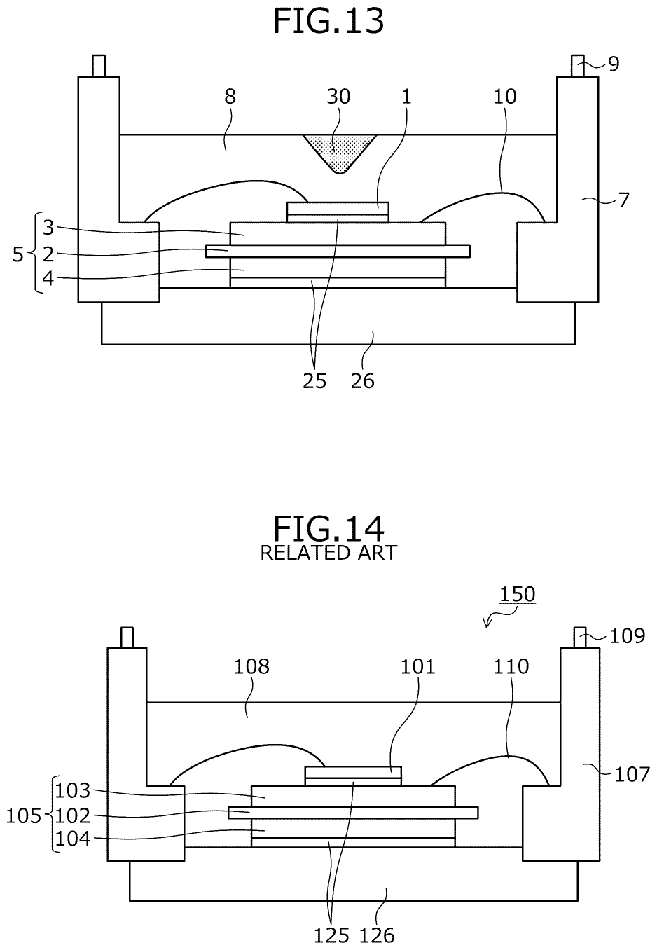

In the sixteenth example, a rectangular shape with a curvature R was used. FIG. 12 is a top view depicting the structure of the sixteenth example of the power semiconductor module according to the embodiment. The storage modulus, the position, and the method of fabrication, etc. were the same as those of the fifteenth example. In the seventeenth example, an inverted triangular shape with a curvature R was used. FIG. 13 is a top view depicting the structure of the seventeenth example of the power semiconductor module according to the embodiment. The storage modulus, the position, and the method of fabrication, etc. were the same as those of the fifteenth example.

The results showed that structures with a cross-sectional shape having an end forming a pointed vertex, such as the rectangular and inverted triangular shapes of the seventh and eighth comparison examples, have a lower effect of improving tolerance against resin cracking during P/C testing compared to the first comparison example, whereas structures with a cross-sectional shape free of pointed vertices, such as the half-moon shape, rectangular shape (with curvature R) and inverted triangular shape (with curvature R) of the fifteenth to seventeenth examples, showed improved tolerance against resin cracking compared to the first comparison example. This is thought to be because a rounded shape free of vertices is effective in preventing resin cracking due to stress concentrating at the vertices in the low elastic modulus region 30. From the results of the fourth experimental example, it was found that the curvature R of corners of polygonal shapes such as rectangles and triangles in a range of at least 0 mm to 0.25 mm is undesirable.

In the fifth experimental example, a method of manufacturing to impart the structure according to the present disclosure in the first method of manufacturing was investigated. The elastic modulus of potting encapsulating resin is generally adjusted by the concentration of the filler added to the resin, and the higher the filler concentration, the higher the elastic modulus. Thus, in preparing the resin used in the low elastic modulus region 30, use of an encapsulating resin with an elastic modulus that has been reduced by reducing the filler concentration is simple. However, in a low elasticity resin in which the filler concentration has been reduced, the viscosity also concurrently decreases and thus, even when this low elasticity liquid resin is directly injected onto the liquid encapsulating resin, the low elasticity resin with low viscosity will not sink but will float, making it impossible to obtain the structure of the present disclosure. Therefore, by utilizing a property that the viscosity of liquid resin generally decreases with heating, the high-viscosity encapsulating resin is heated thereby reducing the viscosity and then, the low-elasticity resin of a low-temperature and high-viscosity is injected therein, whereby the structure according to the present disclosure may be manufactured. In the fifth experimental example, when casting temperatures of the encapsulating resin and the low elasticity resin were each changed to vary viscosity, it was evaluated whether the structure according to the present disclosure could be achieved. The encapsulating resin used in this evaluation was a thermosetting epoxy resin with a composition containing about 73 wt % silica filler. It is known that when the filler concentration in the epoxy resin is increased, the elastic modulus of the cured resin increases and resin viscosity in an uncured state also increases. In the first example, the evaluation was performed using an epoxy resin as a normal encapsulant and a filler-free epoxy resin, which was obtained by removing all the filler from this epoxy resin, as a low elasticity resin. The results are shown in Table 5.

TABLE 5

| | | | ENCAPSULATING RESIN | | | | |
|---|---|---|---|---|---|---|---|
| LOW-VISCOSITY RESIN | | | ENCAPSULATING TEMPERATURE (□) | | | | |
| CASTING | | | 20 | 40 | 60 | 80 | 100 |
| TEMPERATURE | VISCOSITY | | VISCOSITY (Pa□s) | | | | |
| (□) | (Pa□s) | EVALUATION RESULT | 16000 | 8000 | 4000 | 2000 | 1000 |
| 20 | 2000 | VISCOSITY RATIO | 1:0.13 | 1:0.25 | 1:0.5 | 1:1 | 1:2 |
| | | MANUFACTURABILITY | NG1 | NG1 | OK | OK | NG2 |
| 30 | 1400 | VISCOSITY RATIO | 1:0.09 | 1:0.18 | 1:0.35 | 1:0.7 | 1:1.4 |
| | | MANUFACTURABILITY | NG1 | NG1 | OK | OK | NG2 |
| 40 | 1000 | VISCOSITY RATIO | 1:0.06 | 1:0.13 | 1:0.25 | 1:0.5 | 1:1 |
| | | MANUFACTURABILITY | NG1 | NG1 | NG1 | OK | OK |

When the viscosity of the encapsulating resin was assumed to be 1 and the viscosity ratio of the encapsulating resin to the low elasticity resin was between 1:1 and 1:0.35, the structure according to the present disclosure could be manufactured. When the viscosity ratio was 1:0.25 or less, the viscosity of the low-viscosity resin was too low and thus, could not penetrate the encapsulating resin and a structure in which the low-viscosity resin was wet and spread on the encapsulating resin occurred (NG1). Further, when the viscosity ratio was 1:1.4 or less, the viscosity of the encapsulating resin was too low and thus, the low-viscosity resin sank deeply into the encapsulating resin and the desired structure could not be fabricated (NG2). In addition, the viscosity of each resin was varied by controlling the temperature.

In the sixth experimental example, differences in the effectiveness between the first method of manufacturing and the second method of manufacturing was confirmed. In the low elastic modulus region 30, the same resin as that in the fifth example was used and provided directly above the power semiconductor chips 1, in a direction parallel the lateral sides of the module. In addition, the storage modulus of the low elasticity resin after curing was 6 GPa at room temperature. In the first method of manufacturing, the low elasticity resin was produced by casting the resin at a low viscosity resin temperature of 20 degrees C. and an encapsulating resin temperature of 60 degrees C. so that the resin viscosity difference became 1:0.5, followed by thermal curing. In the second method of manufacturing of the fifteenth example, a cured low elasticity resin product that was prepared using a mold so as to have a rod-like shape with a half-moon shape in a cross-sectional view was inserted into an encapsulating resin casted at 60 degrees C. and then the encapsulating resin was thermally cured. The structure of the first comparison example is a same as the structure of the first comparison example of the first experimental example. The results are shown in Table 6.

TABLE 6

| | | EXAMPLE/COMPARISON EXAMPLE | | |
|---|---|---|---|---|
| | | FIRST | | |
| | | COMPARISON | FIFTH | FIFTEENTH |
| | | EXAMPLE | EXAMPLE | EXAMPLE |
| METHOD OF | | NOT PROVIDED | FIRST | SECOND |
| MANUFAC- | | (COMPARISON | METHOD | METHOD |
| TURING | | EXAMPLE) | | |
| P/C | kcyc. | 70 | 105 | 95 |
| TOLERANCE | | | | |
| UNTIL RESIN | | | | |
| CRACKS | | | | |

The results showed that both the first and second methods of manufacturing showed an improvement in the P/C capability compared to the first comparison example, confirming the effect of improving tolerance against resin cracking. Here, it was found that the first method of manufacturing was more effective in improving the resin cracking resistance during P/C. This is because, by injecting a low-filler, low-elasticity resin, which is also a liquid resin, into the encapsulating resin, which is also a liquid resin, the filler diffuses at the interface between the two types of resins before curing of the resins is complete, resulting in a concentration distribution of the filler which is thought to improve the stress relief effect as compared to the second method of manufacturing, in which the interface between the two types of resins is discontinuous. In addition, in the first, second, and third experimental examples, while the first method of manufacturing is used, the same effects are achieved by the second method of manufacturing. Further, in the experimental examples above, while an encapsulating resin for which the storage modulus is 12 GPa is used, even when the storage modulus is different, the low elastic modulus region with a predetermined shape, arrangement, and relative elastic modulus has the same effects.

As described, according to the embodiment, the low elastic modulus region with a low elastic modulus is provided at the surface of the encapsulating resin, directly above the power semiconductor chips where stress tends to concentrate and thus, stress may be reduced and resin cracking may be suppressed.

In the foregoing, the present invention may be variously modified within a range not departing from the spirit of the invention and in the embodiments above, for example, dimensions, dopant concentrations, etc. of regions may be variously set according to necessary specifications. Further, in the embodiments above, in addition to silicon, a wide band gap semiconductor such as silicon carbide (SiC), gallium nitride (GaN), or the like may be used as a semiconductor.

According to the present disclosure, the low elastic modulus region with a low elastic modulus is provided at the surface of the encapsulating resin, directly above the power semiconductor chips where stress tends to concentrate and thus, stress may be reduced and resin cracking may be suppressed.

The semiconductor module and the method of manufacturing the semiconductor module according to the present disclosure achieves an effect in that stress that is repeatedly generated by the thermal expansion and contraction is reduced and resin cracking is suppressed, whereby reliability may be enhanced.

As described, the semiconductor module and the method of manufacturing the semiconductor module according to the present invention are useful for power semiconductor modules used in power converting equipment of, for example, inverters, power source devices of various industrial machines, igniters of automobiles, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor module, comprising:
a stacked substrate;
a semiconductor device mounted on the stacked substrate via a bonding layer;
an encapsulating resin encapsulating the semiconductor device, the bonding layer, and the stacked substrate; and
a low-elastic-modulus element provided at a surface of the encapsulating resin above the semiconductor device, the low-elastic-modulus element having an elastic modulus that is lower than an elastic modulus of the encapsulating resin, wherein
the low-elastic-modulus element has a storage modulus that is a relative elastic modulus of 0.83% or more but less than 100%, when a storage modulus of the encapsulating resin is 100%.

2. The semiconductor module according to claim 1, wherein the relative elastic modulus of the low-elastic-modulus element is in a range of 8% to 75%.

3. The semiconductor module according to claim 1, wherein the relative elastic modulus of the low-elastic-modulus element is in a range of 25% to 50%.

4. The semiconductor module according to claim 1, wherein the low-elastic-modulus element has a stripe-like shape extending parallel to a lateral direction of the semiconductor module in a top view of the semiconductor module.

5. The semiconductor module according to claim 1, wherein the low-elastic-modulus element has a stipe-like shape extending parallel to a lateral direction of the semiconductor module and extending parallel to a longitudinal direction of the semiconductor module in a top view.

6. The semiconductor module according to claim 1, wherein the low-elastic-modulus element is provided directly above the semiconductor device.

7. The semiconductor module according to claim 1, wherein the low-elastic-modulus element has a bottom tip that is blunt and faces the semiconductor device.

8. The semiconductor module according to claim 7, wherein the bottom tip has a curvature of 0.5 mm or more.

9. A method of manufacturing a semiconductor module, the method comprising:
as a first process, mounting a semiconductor device to a stacked substrate via a bonding layer;
as a second process, encapsulating, by a thermosetting resin composition, the semiconductor device, the bonding layer, and the stacked substrate;
as a third process, injecting a resin at a surface of the thermosetting resin composition above the semiconductor device, the resin having an elastic modulus that is lower than an elastic modulus of the thermosetting resin composition; and
as a fourth process, heating and curing the thermosetting resin composition and the resin and thereby forming an encapsulating resin and a low-elastic-modulus element, respectively, such that the low-elastic-modulus element has an elastic modulus that is lower than an elastic modulus of the encapsulating resin.

10. The method of manufacturing the semiconductor module according to claim 9, wherein a ratio of a viscosity of the thermosetting resin composition to a viscosity of the resin is in a range of 1:1 to 1:0.35.

11. A method of manufacturing a semiconductor module, the method comprising:
as a first process, mounting a semiconductor device to a stacked substrate via a bonding layer;
as a second process, encapsulating, by a thermosetting resin composition, the semiconductor device, the bonding layer, and the stacked substrate;
as a third process, inserting a low-elastic-modulus element, which has been precured, at a surface of the thermosetting resin composition above the semiconductor device; and
as a fourth process, heating and curing the thermosetting resin composition and thereby forming an encapsulating resin, wherein
the low-elastic-modulus element has an elastic modulus that is lower than an elastic modulus of the encapsulating resin.
